(19) United States
(12) Patent Application Publication
(10) Pub. No.: US 2023/0170423 A1
(43) Pub. Date: Jun. 1, 2023

(54) MEMORY DEVICE CAPABLE OF MULTI-LEVEL DRIVING

(71) Applicants: The Industry & Academic Coorperation in Chungnam National University (IAC), Daejeon (KR); Korea Institute of Science & Technology Information, Daejeon (KR)

(72) Inventors: Young-Jun YU, Daejeon (KR); Han Seul Kim, Daejeon (KR); Oh Hun Gwon, Daejeon (KR); Jong Yun Kim, Daejeon (KR); Seok-ju Kang, Daejeon (KR); Hye Ryung Byun, Daejeon (KR)

(73) Assignees: The Industry & Academic Coorperation in Chungnam National University (IAC), Daejeon (KR); Korea Institute of Science & Technology Information, Daejeon (KR)

(21) Appl. No.: 17/882,536

(22) Filed: Aug. 6, 2022

(30) Foreign Application Priority Data
Nov. 29, 2021 (KR) 10-2021-0167630

(51) Int. Cl. H01L 29/792

(52) U.S. Cl. CPC H01L 29/7923

(57) ABSTRACT

A memory device includes a gate electrode, a gate insulating layer formed on the gate electrode, a tunneling insulating layer stacked on the gate insulating layer, a channel layer stacked on the tunneling insulating layer, and a source electrode and a drain electrode formed on the channel layer to be spaced apart from each other. The tunneling insulating layer suppresses tunneling of charges from any one of the channel layer and the gate electrode by a voltage applied to each of the gate electrode and the drain electrode, and a density of tunneled charges is set according to the voltage applied to the drain electrode to output and store multiple current levels.

### CROSS REFERENCE TO RELATED APPLICATION

The present application claims priority to Korean Patent Application No. 10-2021-0167630, filed Nov. 29, 2021, the entire contents of which is incorporated herein for all purposes by this reference.

### BACKGROUND OF THE INVENTION

### Field of the Invention

The present disclosure relates to a memory device capable of multi-level driving, and to a technology capable of storing and outputting multi-level data for this purpose.

### Description of the Related Art

A conventional memory device operates on a binary digit system of 0 and 1 with one off-state and one on-state according to an output voltage of a device. In the case of the memory device using the binary digit system, information is transferred to and from each memory by an output voltage, so a significant number of memories are required to quickly transfer a large amount of information.

Although a method of reducing the size of the memory device has been adopted, there is a limit in increasing the number of the devices while reducing the size of the device. Accordingly, attempts have been made for various structural modifications in the memory device, and research has been conducted on storing and outputting multiple current levels with the current density that appears depending on the device type in order to implement a multi-digit system in one memory device.

A conventional multi-digit device has two gate electrodes and is configured to store and output multiple current levels by controlling the voltage applied to each of a source electrode and a drain electrode and the voltage applied to the two gate electrodes. However, power consumption is increased by the two gate electrodes, and the number of levels that can be output is limited even in a multi-digit circuit because a device that stores and outputs multiple current levels is determined according to the voltage applied to the two gates.

Thus, there is a need to develop a device that stores and outputs nⁿ multi-levels by generating multiple current levels according to current density, while optimizing power consumption of the device.

### Documents of Related Art

(Patent document 1) Korean Patent No. 10-2199607 (Jan. 8, 2021)

### SUMMARY OF THE INVENTION

Accordingly, the present disclosure has been made keeping in mind the above problems occurring in the related art, and an objective of the present disclosure is to provide a memory device capable of multi-level driving, the memory device being capable of outputting multiple current levels according to tunneled charges by setting the thickness of an insulating layer according to a digit system to be used in one memory device.

In order to achieve the above objective, according to one aspect of the present disclosure, there is provided a memory device capable of multi-level driving, the memory device including: a gate electrode; a gate insulating layer formed on the gate electrode; a tunneling insulating layer stacked on the gate insulating layer; a channel layer stacked on the tunneling insulating layer; and a source electrode and a drain electrode formed on the channel layer to be spaced apart from each other, wherein the tunneling insulating layer may suppress tunneling of charges from any one of the channel layer and the gate electrode by a voltage applied to each of the gate electrode and the drain electrode, and a density of tunneled charges may be set according to the voltage applied to the drain electrode to output and store multiple current levels.

In a preferred embodiment, the gate electrode may be any one of metals, metal oxides, and silicon.

In a preferred embodiment, the channel layer may be an organic compound or an inorganic compound having any one of n-type, p-type, and ambipolar properties.

In a preferred embodiment, the organic compound may be selected from any one of benzene, naphthalene, anthracene, tetracene, pentacene, hexacene, and heptacene ring compounds consisting of any one element of carbon, oxygen, nitrogen, and hydrogen.

In a preferred embodiment, the inorganic compound may be selected from any one of a two-dimensional compound, a material having a perovskite structure, and a quantum dot material.

In a preferred embodiment, the tunneling insulating layer may be selected from any one of a hexagonal material, an organic compound, and an inorganic oxide.

In a preferred embodiment, the tunneling insulating layer may have a thickness of 10 nm to 200 nm.

In a preferred embodiment, the memory device may further include an encapsulation layer provided on the source electrode and the drain electrode and configured to protect from external oxygen and moisture.

According to another aspect of the present disclosure, there is provided a memory device capable of multi-level driving, the memory device including: a gate electrode; a gate insulating layer formed on the gate electrode; a charge storage layer stacked on the gate insulating layer and configured to store charges; a tunneling insulating layer stacked on the charge storage layer; a channel layer stacked on the tunneling insulating layer; and a source electrode and a drain electrode formed on the channel layer to be spaced apart from each other, wherein the tunneling insulating layer may be fused with at least one of the charge storage layer and the channel layer to form a charge storage fusion layer and a channel fusion layer.

In a preferred embodiment, the charge storage fusion layer may collect charges tunneling from the channel layer.

In a preferred embodiment, the charge storage layer may be selected from any one of a graphene-based material, a metal, a metal oxide, an organic compound, and an inorganic compound.

In a preferred embodiment, any one of the charge storage fusion layer and the channel fusion layer may have a charge mobility lower than that of the channel layer and higher than that of the tunneling insulating layer.

According to the present disclosure, it is possible to quickly process a large amount of information by storing and outputting multiple current levels according to the thickness of the tunneling insulating layer, and to improve the efficiency of the device by optimizing power consumption.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating a first configuration of a memory device capable of multi-level driving according to an embodiment;

FIG. 2 is a view illustrating a second configuration of the memory device capable of multi-level driving according to the embodiment;

FIG. 3 is a first graph illustrating a drain-source current density as a function of a gate voltage for a memory device according to an embodiment;

FIG. 4 is a second graph illustrating a drain-source current density as a function of a gate voltage for a memory device according to an embodiment;

FIG. 5 is a third graph illustrating a drain-source current density as a function of a gate voltage for a memory device according to an embodiment;

FIG. 6 is a graph illustrating thickness-dependent current curves for a tunneling insulating layer according to an embodiment; and

FIGS. 7A and 7B are views illustrating an energy band of tunneled charges between a channel layer and a gate electrode according to an embodiment.

### DETAILED DESCRIPTION OF THE INVENTION

Hereinafter, a memory device capable of multi-level driving according to the present disclosure will be described in detail with reference to the accompanying drawings. For clarity and convenience of explanation, the thickness of the lines or the size of the elements illustrated in the drawings may be exaggerated drawn. Further, technical terms, as will be mentioned hereinafter, are terms defined in consideration of their function in the present disclosure, which may be varied according to the intention of a user, practice, or the like, so that the terms should be defined based on the contents of this specification.

Objectives and effects of the present disclosure can be naturally understood or become clearer by the following description, and the objectives and effects of the present disclosure are not limited by the following description. Further, in the following description of the present disclosure, a detailed description of known functions and configurations incorporated herein will be omitted when it may make the subject matter of the present disclosure rather unclear.

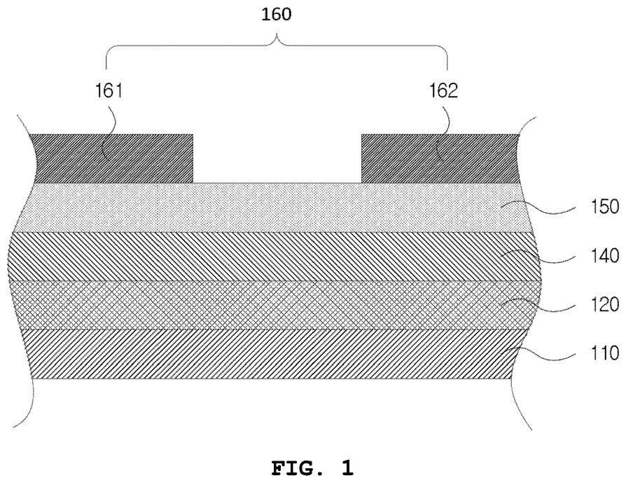

FIG. 1 is a view illustrating a first configuration of a memory device capable of multi-level driving according to an embodiment.

As illustrated in FIG. 1, the first configuration of the memory device capable of multi-level driving according to the embodiment includes a gate electrode 110, a gate insulating layer 120, a tunneling insulating layer 140, a channel layer 150, and a source electrode and a drain electrode 160.

The gate electrode 110 may be any one of metals, metal oxides, and silicon.

Here, the metals may be any one of aluminum, silver, gold, molybdenum, copper, platinum, chromium, nickel, palladium, and titanium.

In addition, the metal oxides may be any one of indium tin oxide (ITO), fluorine-doped tin oxide (FTO), zinc tin oxide (ZTO), indium zinc oxide (IZO), aluminum zinc oxide (AZO), stannous oxide (SnOₓ), indium oxide (In₂Oₓ), zinc oxide (ZnO), molybdenum trioxide (MoO₃), cobalt oxide (CoO), nickel oxide (NiO), tungsten trioxide (WoOₓ), titanium dioxide (TiOₓ), indium gallium zinc oxide (IGZO), indium zinc-tin oxide (IZTO), and indium gallium tin oxide (IGTO).

The gate insulating layer 120 may be formed on the gate electrode 110. The gate insulating layer 120 may be any one of silicon nitrite (SiNₓ), silicon oxide (SiOₓ), hafnium (IV) oxide (HfOₓ), and aluminum oxide (AlₓO_{y}). In addition, the gate insulating layer 120 and the tunneling insulating layer 140 may be made of the same material, and the density of tunneled charges or the amount of tunneled charges generated in the tunneling insulating layer 140 may be changed by the thickness and the gate voltage of the gate electrode 110.

The tunneling insulating layer 140 may be stacked on the gate insulating layer 120.

Here, the tunneling insulating layer 140 may be selected from any one of a hexagonal material, an organic compound, and an inorganic oxide, and may be any one of magnesium, thallium, zinc, and hexagonal boron nitride, aluminum oxide (AlO), zirconium dioxide (ZrO), hafnium (IV) oxide (HfO), and titanium dioxide (TiO). The tunneling insulating layer 140 may have a thickness of 10 nm to 200 nm.

The channel layer 150 may be stacked on the tunneling insulating layer 140.

Here, the channel layer 150 may be an organic compound or an inorganic compound having any one of n-type, p-type, and ambipolar properties. In this case, the organic compound may be selected from any one of benzene, naphthalene, anthracene, tetracene, pentacene, hexacene, and heptacene ring compounds consisting of any one element of carbon, oxygen, nitrogen, and hydrogen. The organic compound may be any one of dinaphtho[2,3-b:2′,3′-f]thieno[3,2-b]thiophene (DNTT), copper hexadecafluorophthalocyanine (F16CuPc), polystyrene, poly(9,9-dioctylfluorene-co-benzothiadiazole (F8BT), fullerene, poly-(methacrylic acid) (PMAA), poly (9,9-dioctylfluorenyl-2,7-diyl) (PF), poly[(9,9-dioctylfluorenyl-2,7-diyl)-alt-(benzo[2,1,3]thiadiazol-4,8-diyl)] (PFBT), polyaniline (PANI), polypyrrole, poly(3,4-ethylenedioxythiophene), polythiophene, poly(p-phenylene vinylene), and poly(3,4-ethylenedioxythiophene):poly(styrenesulfonate) (PEDOT:PSS).

The inorganic compound may be selected from any one of a two-dimensional compound, a nanoparticle, a material having a perovskite structure, and a quantum dot material. The inorganic compound may be any one of molybdenum sulfide (MoS₂), tungsten disulfide (WS₂), molybdenum diselenide (MoSe₂), tungsten diselenide (WSe₂), methylammonium lead iodide (CH₃NH₃PbI₃: MAPbI₃), formamidinium lead iodide (HC(NH₂)₂PbI₃, FAPbI₃), and calcium titanate (CaTiO₃).

The source electrode and the drain electrode 160 may be formed on the channel layer 150 to be spaced apart from each other. In this case, an encapsulation layer for protecting from external oxygen and moisture may be further included on the source electrode and the drain electrode 160.

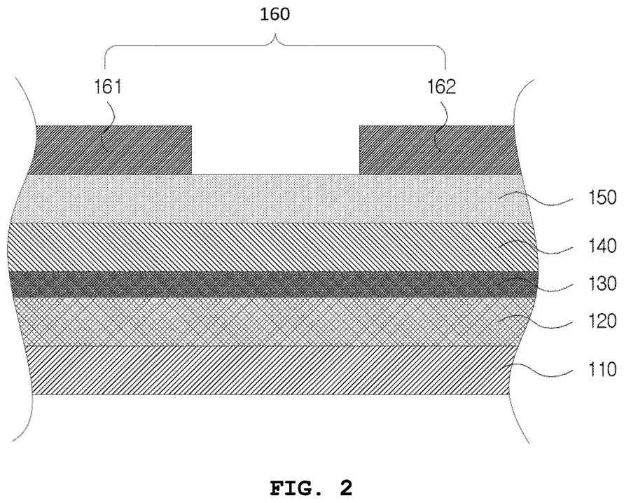

FIG. 2 is a second configuration view illustrating the memory device capable of multi-level driving according to the embodiment.

As illustrated in FIG. 2, the second configuration of the memory device capable of multi-level driving according to the embodiment includes a gate electrode 110, a gate insulating layer 120, a charge storage layer 130, a tunneling insulating layer 140, a channel layer 150, and a source electrode and a drain electrode 160.

The gate electrode 110 may be any one of metals, metal oxides, and silicon.

The gate insulating layer 120 may be formed on the gate electrode 110.

The charge storage layer 130 may be stacked on the gate insulating layer 120. Here, the charge storage layer 130 may be selected from any one of a graphene-based material, a metal, a metal oxide, an organic compound, and an inorganic compound. The graphene-based material may be any one of a carbon nanotube, graphene oxide, and graphite, but is not necessarily limited to the above-described materials. In addition, the metal, the metal oxide, the organic compound, and the inorganic compound are not limited as long as they are used for collecting or trapping charges.

The tunneling insulating layer 140 may be stacked on the charge storage layer 130.

Here, the tunneling insulating layer 140 may be fused with at least one of the charge storage layer 130 and the channel layer 150 to form a charge storage fusion layer and a channel fusion layer. The tunneling insulating layer 140 may further include any one of an organic layer made of an organic material and an inorganic layer made of an inorganic material.

The charge storage fusion layer may collect charges tunneling from the channel layer 150, and the channel fusion layer may have a charge mobility lower than that of the channel layer 150 and higher than that of the tunneling insulating layer 140.

The channel layer 150 may be stacked on the tunneling insulating layer 140.

The source electrode and the drain electrode 160 may be formed on the channel layer 150 to be spaced apart from each other.

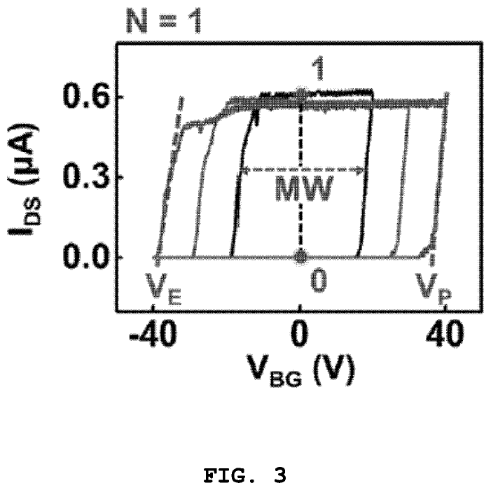

FIGS. 3 to 5 are graphs illustrating a drain-source current density as a function of a gate voltage for the memory device according to the embodiment, illustrating changes in current density according to the thickness of the tunneling insulating layer 140.

FIG. 3 is a first graph illustrating a drain-source current density as a function of a gate voltage for a memory device according to an embodiment.

As illustrated in FIG. 3, the first graph illustrating the drain-source current density as the function of the gate voltage for the memory device according to the embodiment illustrates a drain-source current density measured when the back gate voltage sweeps from −20 V to +20 V, −30 V to +30 V, and −40 V to +40 V in the memory device in which the tunneling insulating layer 140 is formed thin.

The slope increases or decreases steeply for each sweep range, and the number of current levels that can be output is determined according to the drain-source current.

In this case, when the thickness of the tunneling insulating layer 140 is small, charges easily tunnel from any one of the channel layer 150 and the gate electrode 110. Thus, a current is formed in the channel layer 150 very quickly at a time point when a voltage is applied to each of the gate electrode 110 and the drain electrode, so that the number of levels that can be generated at a specific voltage and a specific current density is limited.

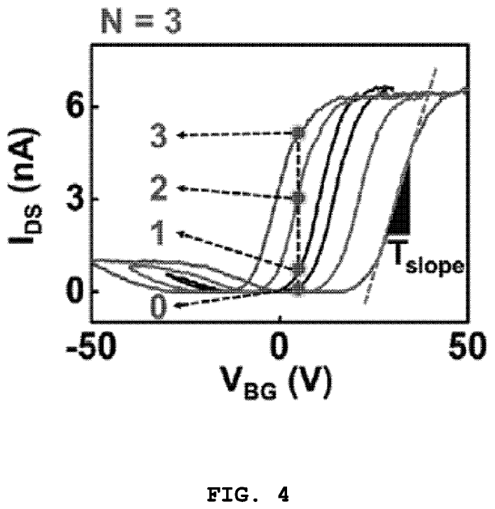

FIG. 4 is a second graph illustrating a drain-source current density as a function of a gate voltage for a memory device according to an embodiment.

As illustrated in FIG. 4, the second graph illustrating the drain-source current density as the function of the gate voltage for the memory device according to the embodiment illustrates a drain-source current density measured when the back gate voltage sweeps from −30 V to +30 V, −40 V to +40 V, and −50 V to +50 V in the memory device in which the tunneling insulating layer 140 is formed thick.

In this case, different drain-source current densities are formed at the same back gate voltage for each back gate voltage sweep range, and different memory windows are formed for each back gate voltage sweep range, so that the number of levels that can be generated at the same back gate voltage increases.

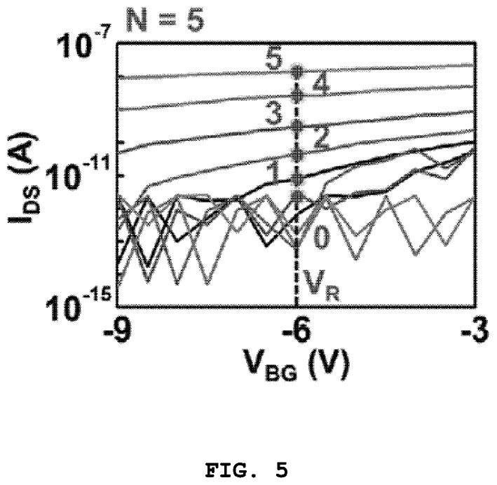

FIG. 5 is a third graph illustrating a drain-source current density as a function of a gate voltage for a memory device according to an embodiment.

As illustrated in FIG. 5, the third graph illustrating the drain-source current density as the function of the gate voltage for the memory device according to the embodiment illustrates a drain-source current density measured when the back gate voltage sweeps from −30 V to +30 V, −40 V to +40 V, −50 V to +50 V, and −60 V to +60 V in the memory device in which the tunneling insulating layer 140 is formed thicker.

In this case, different drain-source current densities are formed at the same back gate voltage for each back gate voltage sweep range, and different memory windows are formed for each sweep range, so that multiple current levels can be set in different back gate voltage ranges with the drain-source current densities different for each sweep range of the back gate voltage. The voltage applied to the drain and source electrodes may be set to 0.1 V to 10 V.

In the graphs illustrated in FIGS. 3 to 5, the tunneling insulating layer 140 of each device has a different thickness, and the range of application of the back gate voltage is varied according to the thickness of the tunneling insulating layer 140.

Thus, the thickness of the tunneling insulating layer 140 of the memory device may be 10 nm≤x<50 nm in the first graph illustrated in FIG. 3, may be 50 nm≤x<100 nm in the second graph illustrated in FIG. 4, and may be 100 nm≤x≤200 nm in the third graph illustrated in FIG. 5. However, the thickness of the tunneling insulating layer 140 is not necessarily limited to the above-described ranges.

In other words, the number of bits that can be generated in the memory device may be determined by the number of current levels that can be generated at the same back gate voltage by the sweep range and number of sweeps of the back gate voltage according to the thickness of the tunneling insulating layer 140.

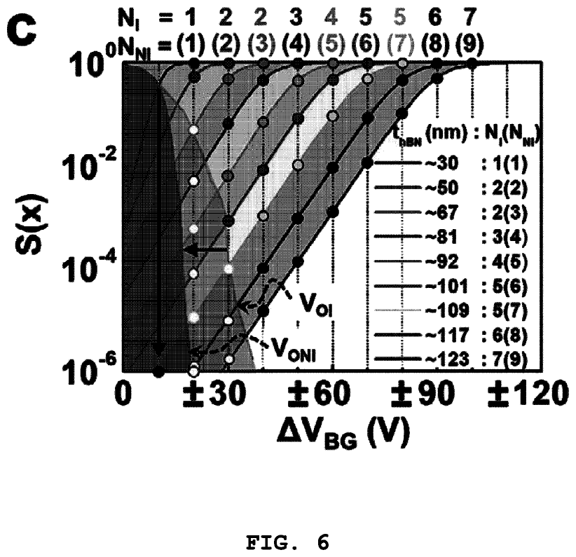

FIG. 6 is a graph illustrating thickness-dependent current curves for a tunneling insulating layer 140 according to an embodiment.

As illustrated in FIG. 6, the thickness-dependent current curves for the tunneling insulating layer 140 according to the embodiment represent the number of current levels that can be generated in the sweep range of the back gate voltage by subdividing the thickness of the tunneling insulating layer 140 for each of first to ninth devices.

First, the thickness x of the tunneling insulating layer 140 may be set to 10 nm≤x<30 nm, 30 nm≤x<50 nm, 50 nm≤x<67 nm, 67 nm≤x<81 nm, 81 nm≤x<92 nm, 92 nm≤x<101 nm, 101 nm≤x<109 nm, 109 nm≤x<117 nm, and 117 nm≤x<129 nm for the first to ninth devices, respectively. In this case, when the back gate voltage dependent on the thickness of the tunneling insulating layer 140 sweeps from −120 V to +120 V, 1, 2, 2, 3, 4, 5, 5, 6, and 7 current levels may be generated in the order of decreasing the thickness of the tunneling insulating layer 140. Here, x is adopted to determine the number of each current level according to the embodiment and is not necessarily limited to the above-described boundaries, and the boundaries of x that determines the number of each current level may be changed according to the material constituting each device.

By determining the thickness of the tunneling insulating layer 140 in this manner, the number of multi-levels to be generated in one device can be preset before manufacturing the memory device. This may be expressed by the following equation.

$${S}_{t h B N} ( V ) = \frac{{I}_{s a t}}{1 + {e}^{- P ( V - {V}^{0} )}} \qquad [ Equation 1 ]$$

In Equation 1, Iₛₐₜ is 1, T_{hBN} is the thickness of the tunneling insulating layer 140, V⁰ is the middle value of the back gate voltage dependent on the thickness of the tunneling insulating layer 140, and the logistic growth rate p is set to ensure that the slope of Sₜ_{_{hBN}} is satisfied. This may be calculated and expressed by the following equation.

$$Δ {S}_{t h B N} \vert \begin{matrix}s = 0.5 {I}_{s a t} \\ s = 0.3 {I}_{s a t}\end{matrix} = {T}_{s l o p e}^{fit} ( {t}_{h B N} ) \qquad [ Equation 2 ]$$

In Equation 2, each S_{thBN}(V) satisfying V=ΔV_{BG} with the condition |ΔV_{BG}|>V₀ may be set as levels that can be generated. Here, although the number of levels according to the embodiment has been described for only the first to ninth devices, the number of levels that can be generated may be varied according to variations in the tunneling insulating layer 140 in a memory device to be manufactured later.

The thickness of the tunneling insulating layer 140 converges to 60 nm when the gate voltage of an ideal memory device is 20 V, but the average slope at 60 nm<t_{hBN}<120 nm is almost negligible. Thus, the number of levels N=3 is counted as 2, losing 1 level for a range of ΔV_{BG}=±20 V to ±40 V due to the thickness of the tunneling insulating layer 140=60 nm to 100 nm, a closed memory window (closed MW<1 V), and the charges tunneling between the channel layer 150 and the charge storage layer 130.

On the contrary, in an open memory window (open MW>2 V), when the back gate voltage is −20 V to +20 V, the thickness of the tunneling insulating layer 140 converges to 93 nm. In other words, a loss of 1 level may occur even with the same thickness of the tunneling insulating layer 140 due to the closed memory window and the open memory window.

Consequently, the 1:1 relationship between the thickness of the tunneling insulating layer 140 and the number of current levels may be constructed as a form of the simple parabolic equation by fitting the result of a multi-level generation map as the following equations.

$$γ = {A}_{I} + {B}_{t B N} - {C}_{tBN}^{2} \qquad [ Equation 3 ]$$

$$γ = {A}_{NI} + {B}_{t B N} - {C}_{tBN}^{2} \qquad [ Equation 4 ]$$

$${A}_{I} = \{ \begin{matrix}{A}_{NI} if {t}_{h B N} < 58 nm \\ {A}_{NI} - 1 if 58 nm < {t}_{hBN} < 105 nm \\ {A}_{NI} - 2 if 105 nm < {t}_{hBN}\end{matrix} \qquad [ Equation 5 ]$$

In Equations 3 to 5, I is an ideal case, NI is a non-ideal case, and A, B, and C are constants, respectively. Here, the thickness t_{hBN} values of the tunneling insulating layer 140 are the points at which the intersections of S(V) with V_{OI} and V_{ONI} make the A_{I}-A_{NI} relationship different. Specifically, the critical t_{hBN} values of the tunneling insulating layer 140 represent the boundaries for separating the closed (ideal) and open (non-ideal) MW regions.

Thus, charge tunneling can be suppressed with the increase in the thickness t_{hBN} of the tunneling insulating layer 140 in both the closed and open memory windows. Because the number of levels N has to be an integer, the N value expected from the equations is obtained by rounding off y. This may be expressed by the following equation.

N=[γ+0.5] [Equation 6]

In Equation 6, [ ] represents the Gauss sign. In other words, the exact N value can be numerically estimated considering the critical conditions of the thickness of the tunneling insulating layer 140 and ΔV_{BG}.

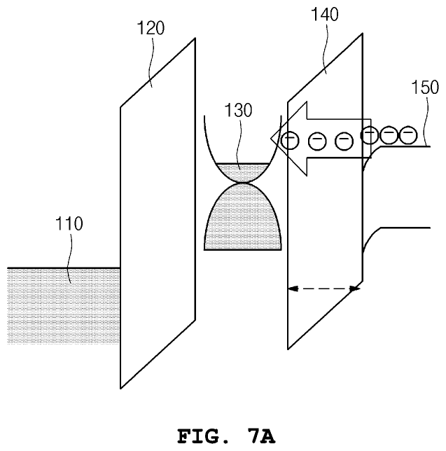

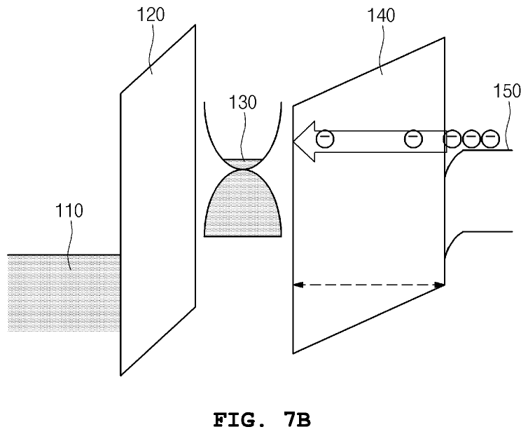

FIGS. 7A and 7B are views illustrating an energy band of tunneled charges between a channel layer 150 and a gate electrode 110 according to an embodiment.

As illustrated in FIGS. 7A and 7B, the energy band of the tunneled charges between the channel layer 150 and the gate electrode 110 according to the embodiment may be divided into a case where the tunneling insulating layer 140 is thin and a case where the tunneling insulating layer 140 is thick.

In the case where the tunneling insulating layer 140 is thin, the density of the tunneled charges is high, and the tunneled charges may be stored in the charge storage layer 130. On the other hand, in the case where the tunneling insulating layer 140 is thick, the density of the tunneled charges is low, so that a current is generated in the channel layer 150 at a higher voltage than in the device in which the tunneling insulating layer 140 is thin. Thus, as the thickness of the tunneling insulating layer 140 increases, the slope of the current curve may decrease.

While the present disclosure has been described with reference to exemplary embodiments thereof, those skilled in the art will appreciate that the disclosure is not limited to the disclosed exemplary embodiments but may be variously modified within the scope of the present disclosure. Therefore, the scope of the present disclosure should not be limited to the above-described embodiments but should be determined by the appended claims, and all modifications or variations derived from the meaning and scope of the appended claims and their equivalents should be construed as being included in the range of the present disclosure.

What is claimed is:

1. A memory device capable of multi-level driving, the memory device comprising:
a gate electrode;
a gate insulating layer formed on the gate electrode;
a tunneling insulating layer stacked on the gate insulating layer;
a channel layer stacked on the tunneling insulating layer; and
a source electrode and a drain electrode formed on the channel layer to be spaced apart from each other,
wherein the tunneling insulating layer suppresses tunneling of charges from any one of the channel layer and the gate electrode by a voltage applied to each of the gate electrode and the drain electrode, and a density of tunneled charges is set according to the voltage applied to the drain electrode to output and store multiple current levels.

2. The memory device of claim 1, wherein the gate electrode is any one of metals, metal oxides, and silicon.

3. The memory device of claim 1, wherein the channel layer is an organic compound or an inorganic compound having any one of n-type, p-type, and ambipolar properties.

4. The memory device of claim 3, wherein the organic compound is selected from any one of benzene, naphthalene, anthracene, tetracene, pentacene, hexacene, and heptacene ring compounds consisting of any one element of carbon, oxygen, nitrogen, and hydrogen.

5. The memory device of claim 3, wherein the inorganic compound is selected from any one of a two-dimensional compound, a material having a perovskite structure, and a quantum dot material.

6. The memory device of claim 1, wherein the tunneling insulating layer is selected from any one of a hexagonal material, an organic compound, and an inorganic oxide.

7. The memory device of claim 1, wherein the tunneling insulating layer has a thickness of 10 nm to 200 nm.

8. The memory device of claim 1, further comprising an encapsulation layer provided on the source electrode and the drain electrode and configured to protect from external oxygen and moisture.

9. A memory device capable of multi-level driving, the memory device comprising:
a gate electrode;
a gate insulating layer formed on the gate electrode;
a charge storage layer stacked on the gate insulating layer and configured to store charges;
a tunneling insulating layer stacked on the charge storage layer;
a channel layer stacked on the tunneling insulating layer; and
a source electrode and a drain electrode formed on the channel layer to be spaced apart from each other,
wherein the tunneling insulating layer is fused with at least one of the charge storage layer and the channel layer to form a charge storage fusion layer and a channel fusion layer.

10. The memory device of claim 9, wherein the charge storage fusion layer collects charges tunneling from the channel layer.

11. The memory device of claim 9, wherein the charge storage layer is selected from any one of a graphene-based material, a metal, a metal oxide, an organic compound, and an inorganic compound.

12. The memory device of claim 9, wherein any one of the charge storage fusion layer and the channel fusion layer has a charge mobility lower than that of the channel layer and higher than that of the tunneling insulating layer.
